(19) United States
(12) Patent Application Publication
(10) Pub. No.: US 2026/0136862 A1
(43) Pub. Date: May 14, 2026

(54) MANUFACTURING METHOD FOR DICING A WAFER

(71) Applicant: Taiwan-Asia Semiconductor Corporation, Hsinchu City (TW)

(72) Inventor: Chia-Jung Chia, Hsinchu City (TW)

(21) Appl. No.: 19/213,243

(22) Filed: May 20, 2025

(30) Foreign Application Priority Data
Nov. 12, 2024 (TW) 113143410

(51) Int. Cl. H01L 21/78; B23K 26/38; H01L 21/304; H01L 23/544

(52) U.S. Cl. CPC H10P 54/00; B23K 26/38; H10P 52/00; H10W 46/00; H10W 46/501

(57) ABSTRACT

A manufacturing method for dicing a wafer having multiple non-rectangular dies is provided. The manufacturing method comprises the following steps. First, arrange the dies on the wafer such that the edges of each die are aligned in a straight line and partitions are formed between the adjacent dies. Next, multiple markers are disposed individually in each partition. Then, after initially imaging and locating each marker, a straight-line cut is performed along the aligned edges of the dies. After rotating the wafer to a new angle and imaging to locate each marker, a straight-line cut along another set of aligned and uncut edges of the dies are performed. Finally, repeat the previous step until all edges of each die have been straight-line cut.

### CROSS-REFERENCES TO RELATED APPLICATIONS

This application claims the benefit of priority to Taiwanese Patent Application No. 113143410 filed on Nov. 12, 2024, which is hereby incorporated by reference in its entirety.

### BACKGROUND OF THE INVENTION

### Field of the Invention

The present invention relates to a manufacturing method for dicing a wafer, and in particular to particularly a method for dicing a wafer into non-rectangular dies.

### Descriptions of the Related Art

A photosensitive chip is a photoelectric conversion element that generates a corresponding current or voltage change when light irradiates it. Photosensitive chips are widely used in various optical instruments, such as optical communication, photoelectric detection, automatic brightness adjustment, spectral analysis, photosensitive circuits, light detectors, and cameras. They are typically employed to detect light intensity, measure spectra, or sense optical signals. As shown in FIG. 1, a wafer is conventionally diced using a dicing saw in a straight-line cut manner for resulting in rectangular chips, which are the most common die shape. However, when such rectangular chips are applied to photosensitive modules in wearable devices, which have gained popularity in recent years, they fail to meet the requirement for maximizing the distribution area. Consequently, to address the need for maximizing the distribution area of photosensitive chips, various die shapes have been developed, with hexagonal dies being the most common, as illustrated in FIG. 2.

FIG. 2 depicts a conventional layout of hexagonal dies on a wafer 1. The die 10 arrangement shown represents the densest packing layout, which maximizes the usable area of the wafer. However, because the contours of hexagonal dies cannot be aligned into a continuous straight line, traditional low-cost dicing saw methods, as shown in FIG. 1, cannot be used to dice the wafer after epitaxial growth processes for the die 10 been completed. Even with laser scribing, the conventional cleaving process cannot be applied to separate the wafer. Instead, plasma etching is required for die separation. However, plasma etching a wafer with a thickness of 100 to 300 micrometers (μm) introduces disadvantages such as high cost, time consumption, and low yield, all of which urgently need to be improved.

### SUMMARY OF THE INVENTION

The main objective of the present invention is to provide an innovative manufacturing method for dicing a wafer, particularly suited for cutting dies with non-rectangular shapes on the wafer. This method not only enables the use of traditional straight-line cutting processes but also enhances the accuracy of wafer dicing equipment by placing markers in the partitions between dies on the wafer. These markers ensure consistent imaging recognition across different angles for improving the identifiability of imaging positioning and ensuring the accuracy of angle determination across different cutting equipment for thereby increasing the precision of wafer dicing.

To achieve the above objective, the present invention provides a manufacturing method for dicing a wafer having a plurality of dies with non-vertical internal angles. The method includes the following steps. First, arrange the dies on the wafer such that the edges of each die are aligned in a straight line, with a partition formed among adjacent dies. Next, dispose a plurality of markers in each partition. Then, after initially imaging to locate each marker, perform a straight-line cut along the aligned edges of the dies. Subsequently, after rotating the wafer by an angle and imaging to locate each marker again, performing a straight-line cut along the aligned, uncut edges of the dies. Finally, repeat the previous step until all edges of each die have been straight-line cut.

In one embodiment of a manufacturing method for dicing a wafer of the present invention, when each die is a 120° internal-angle die, the edges of the dies on the wafer are aligned to form a plurality of first slope straight lines, a plurality of second slope straight lines, and a plurality of third slope straight lines.

In one embodiment of a manufacturing method for dicing a wafer of the present invention, the initial imaging to locate each marker is to perform a straight-line cut to each first slope straight line on the wafer after locating each of the first slope straight lines in a horizontal status.

In one embodiment of a manufacturing method for dicing a wafer of the present invention, the step of rotating the wafer by an angle and imaging to locate each marker includes the steps of rotating the wafer by 60°, locating each second slope straight line in a horizontal status, and then straight-line cutting each second slope straight line on the wafer; and rotating the wafer by another 60°, positioning each third slope straight line in a horizontal status, and then straight-line cutting each third slope straight line on the wafer.

In one embodiment of a manufacturing method for dicing a wafer of the present invention, the step of straight-line cutting the wafer is performed using a dicing saw.

In one embodiment of a manufacturing method for dicing a wafer of the present invention, the step of disposing a plurality of markers in each partition is performed by forming each marker in each partition using a photolithography process.

In one embodiment of a manufacturing method for dicing a wafer of the present invention, the step of arranging the dies on the wafer to form partitions between adjacent dies involves arranging the adjacent dies to surround and form triangular areas.

To achieve the above objective, the present invention also provides a manufacturing method for dicing a wafer having a plurality of hexagonal dies, comprising the following steps. Arrange the hexagonal dies on the wafer such that one edge of each hexagonal die is aligned to form a plurality of first slope straight lines, a plurality of second slope straight lines, and a plurality of third slope straight lines, with a partition formed among adjacent hexagonal dies, wherein the area of each partition is smaller than the area of each hexagonal die. Dispose a plurality of markers in each partition. After initially imaging to locate each marker to position the first slope straight lines in a horizontal status, perform a straight-line cut along each first slope straight line. After rotating the wafer by 60° and imaging to locate each marker to position the second slope straight lines in a horizontal status, perform a straight-line cut along each second slope straight line. After rotating the wafer by another 60° and imaging to locate each marker to position the third slope straight lines in a horizontal status, perform a straight-line cut along each third slope straight line.

In one embodiment of a manufacturing method for dicing a wafer of the present invention, the step of straight-line cutting the wafer is performed using a dicing saw.

In one embodiment of a manufacturing method for dicing a wafer of the present invention, the step of disposing a plurality of markers in each partition is performed by forming each marker in each partition using a photolithography process.

In one embodiment of a manufacturing method for dicing a wafer of the present invention, the step of arranging the hexagonal dies on the wafer to form partitions among adjacent hexagonal dies involves arranging the adjacent hexagonal dies to surround and form triangular areas.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic top view of a conventional wafer layout with rectangular dies;

FIG. 2 is a schematic top view of a conventional wafer layout with hexagonal dies;

FIG. 3 is a schematic top view of a wafer layout with hexagonal dies according to an embodiment of the present invention;

FIG. 4 is a partial enlarged schematic view of FIG. 3;

FIGS. 5A to 5C are partial enlarged schematic views of FIG. 4 at different rotation angles;

FIG. 6 is a schematic top view of a wafer layout with hexagonal dies according to another embodiment of the present invention;

FIGS. 7A to 7C are partial enlarged schematic views of FIG. 6 at different rotation angles; and

FIG. 8 is a flowchart of the wafer dicing process according to the present invention.

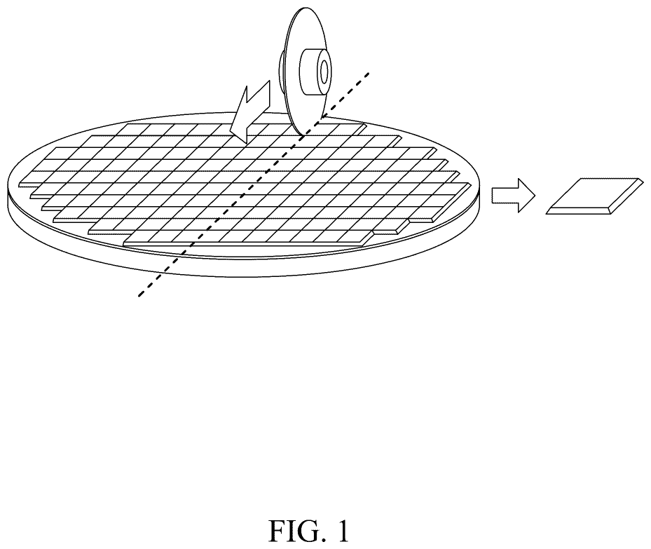

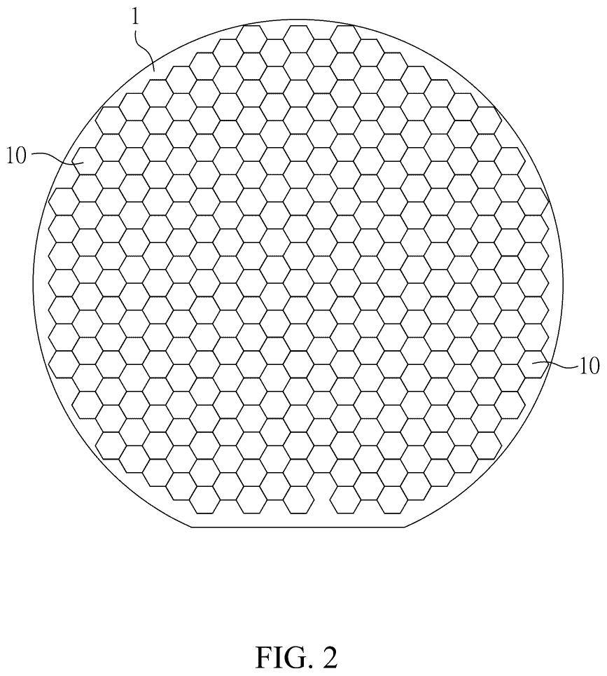

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

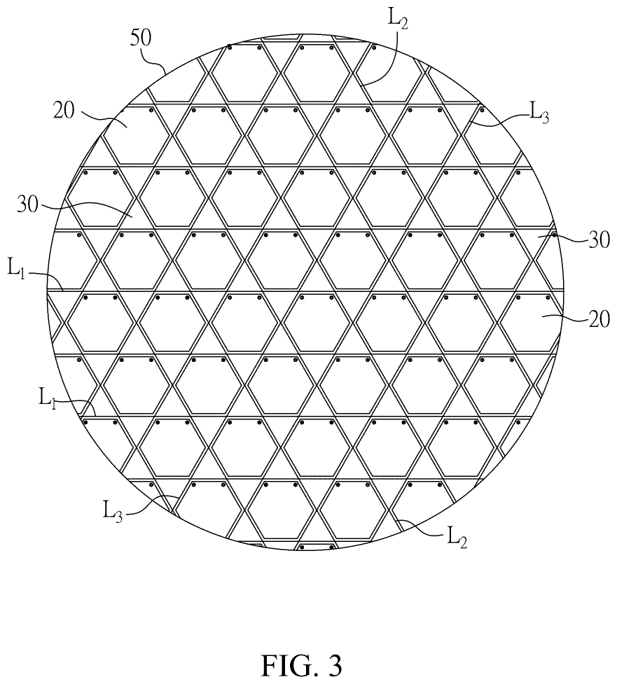

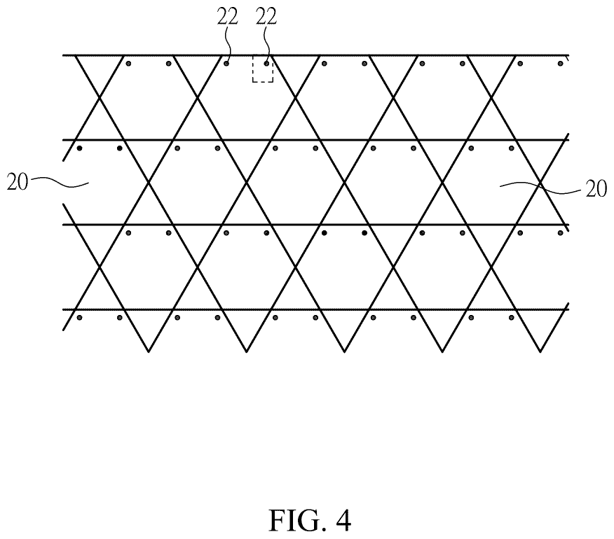

Referring to FIG. 3, a schematic top view of a wafer 50 is shown. The wafer 50 contains a plurality of photosensitive dies before dicing with a partition 30 formed among adjacent dies 20. The area of each partition 30 is smaller than that of each die 20. Regarding die appearance, the dies 20 are hexagonal dies with non-90° internal angles, specifically having 120° internal angles. The partition 30 surrounded by the hexagonal dies is a triangular area. Additionally, two electrodes 22 are disposed on the upper edge of each die 20 as positive and negative contact points, as shown in the partial enlarged schematic view of FIG. 4. Although the die 20 arrangement on the wafer 50 in FIG. 3 is not the densest packing, its key feature is that the six sides of each hexagonal die are aligned with one another to form multiple straight lines for facilitating subsequent straight-line cutting with a dicing saw. These straight lines can be classified by slope into three types: first slope straight lines L₁, second slope straight lines L₂, and third slope straight lines L₃. Specifically, as shown in FIG. 3, the first slope straight line L₁ has a slope of 0, the second slope straight line L₂ has a slope of \sqrt{3}, and the third slope straight line L₃ has a slope of −\sqrt{3}.

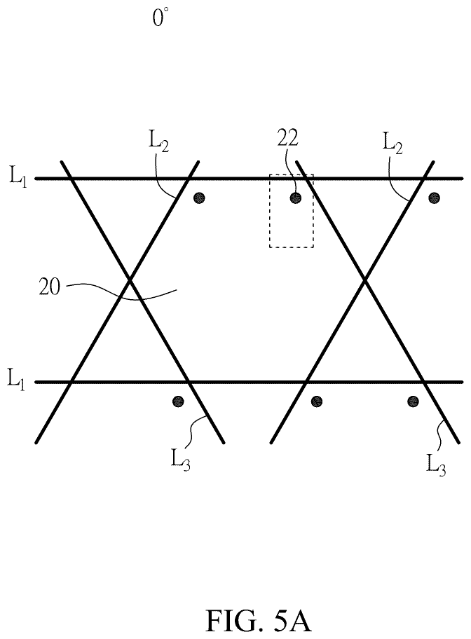

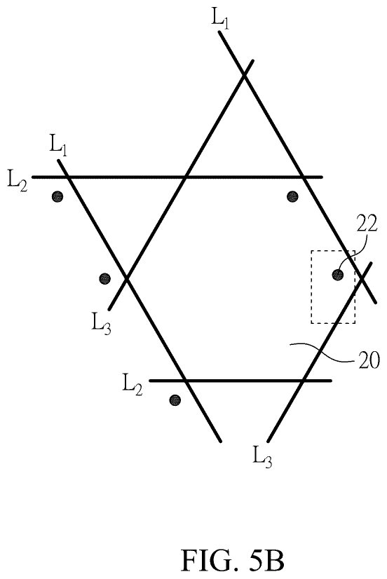

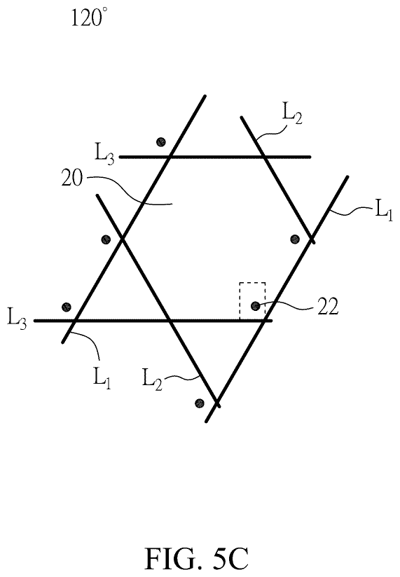

The die arrangement in FIG. 3 allows the edges of each die to be concatenated into long straight lines for facilitating straight-line cutting on the wafer with a dicing saw and reducing the process costs associated with laser or plasma cutting. It should be noted that before dicing the wafer with a dicing saw, the cutting equipment must use imaging to locate and identify the orientation of the die edges. Cutting proceeds only after the imaging confirms the die edge orientation is correct to prevent erroneous cuts that could damage the dies. Referring to FIG. 4 and FIG. 5A to FIG. 5C, when imaging to locate die edges, one of the two electrodes 22 on the die 20 can be used as a reference positioning point, as indicated by dotted frame in FIG. 4.

Specifically, during initial imaging, one electrode 22 on the die 20 is selected as the reference positioning point. After the imaging confirms the die edge orientation is correct, horizontal straight-line cutting is performed. At this point, the first slope straight line L₁ exhibits a slope of 0 (horizontal status), and the cutting equipment performs straight-line cutting along the edges of each die 20 aligned into the first slope straight line L₁ on the wafer 50, as shown in FIG. 5A. Next, the entire wafer 50 is rotated by an angle, e.g., 60°, changing the slope of the second slope straight line L₂ from \sqrt{3} to a horizontal status. After imaging confirms the orientation is correct, the cutting equipment performs another straight-line cut along the edges of each die 20 aligned into the second slope straight line L₂, as shown in FIG. 5B. Similarly, the wafer is rotated another 60°, bringing the third slope straight line L₃ into a horizontal status after two rotations. After imaging confirms the orientation, the cutting equipment performs another straight-line cut along the edges of each die 20 aligned into the third slope straight line L₃, as shown in FIG. 5C.

While the aforementioned wafer dicing method overcomes the drawback of laser or plasma cutting required for non-rectangular dies, using one electrode on the die as a reference positioning point for image recognition still carries the risk of recognition failure. Specifically, as shown in FIGS. 5A to 5C, when one electrode 22 is designated as the reference positioning point and the wafer is rotated to 0°, 60°, and 120°, the orientation of each die 20 on the wafer 50 changes accordingly. These orientation differences create challenges for image recognition, as the dies produce three different images at the three different angles and lead to confusion in grayscale values during imaging recognition. This can further result in erroneous identification and affect the accuracy of wafer dicing.

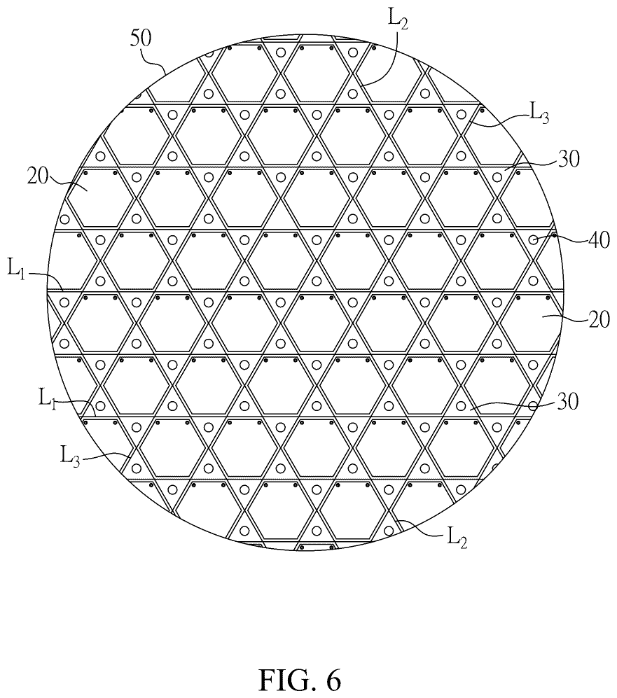

In view of this, refer to FIG. 6, which illustrates a preferred embodiment of the wafer dicing method of the present invention. This preferred embodiment involves disposing a marker 40 in the partition 30 among adjacent dies 20 on the wafer 50 to assist with imaging recognition during wafer dicing. The marker 40 is formed in each partition 30 during the wafer fabrication stage using a photolithography process. Specifically, as shown in FIG. 6, since a marker 40 is present at the center of the partition 30 among adjacent dies 20 as a reference positioning point for imaging recognition, the images obtained at various angles during a wafer dicing process similar to the one described above remain substantially consistent. This avoids the aforementioned issue of grayscale value confusion in imaging recognition for improving the identifiability of imaging positioning. It also enhances the accuracy of recognizing the wafer rotation angle for thereby increasing the precision of wafer dicing.

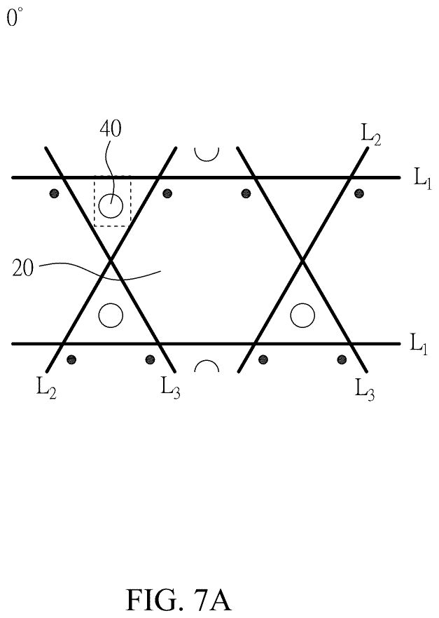

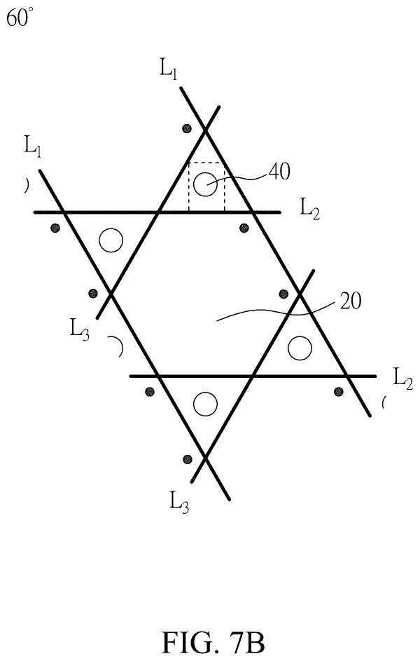

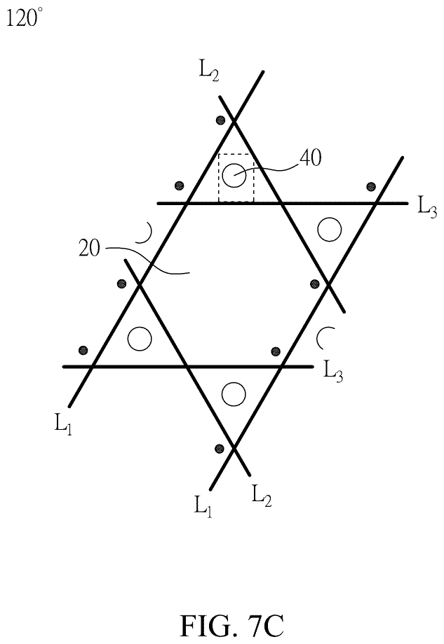

Specifically, similar to the previous description, during initial imaging, one marker 40 between dies 20 is selected as the reference positioning point. After imaging confirms the die edge orientation is correct, horizontal straight-line cutting is performed. At this point, the first slope straight line L₁ exhibits a slope of 0 (horizontal status), and straight-line cutting is performed along the edges of each die 20 aligned into the first slope straight line L₁ on the wafer 50, as shown in FIG. 7A. Next, after rotating the entire wafer by 60°, the second slope straight line L₂ is brought into a horizontal status. After imaging confirms the orientation is correct, the cutting equipment performs another straight-line cut along the edges of each die 20 aligned into the second slope straight line L₂, as shown in FIG. 7B. Similarly, the wafer is rotated another 60°, bringing the third slope straight line L₃ into a horizontal status after two rotations. After imaging confirms the orientation, the cutting equipment performs another straight-line cut to the edges of each die 20 aligned into the third slope straight line L₃, as shown in FIG. 7C. After three cuts, all edges of each die 20 on the wafer 50 are successfully straight-line cutting with a dicing saw. Subsequently, traditional wafer cleaving methods can be applied to separate the non-rectangular dies completely. Furthermore, while hexagonal dies are used as an example to illustrate the wafer dicing method of the present invention, but not limited thereto. The method is also applicable to cutting dies of other shapes, such as parallelograms or octagons.

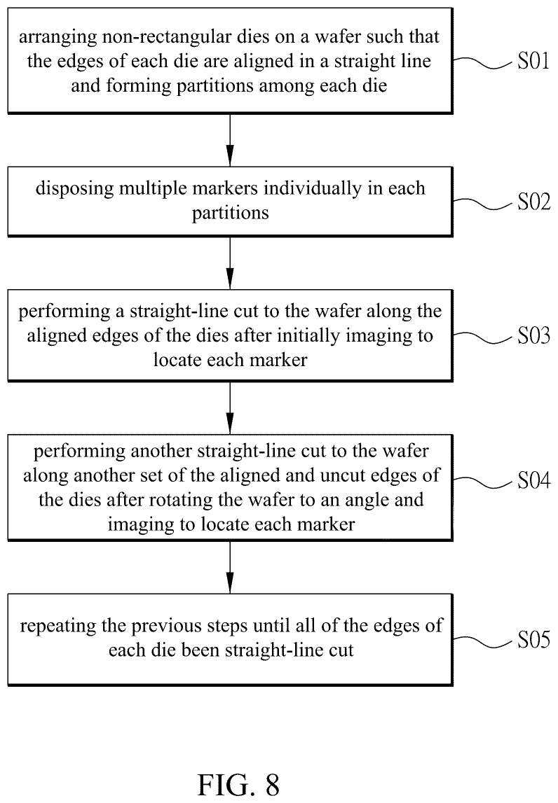

Referring to FIG. 8, a flowchart of the wafer dicing process of the present invention is shown. First, in step S01, a plurality of dies are arranged on the wafer such that one edge of each die is aligned in a straight line, with a partition formed among adjacent dies, and the area of each partition is smaller than that of each die. In step S02, a plurality of markers are disposed in each partition. Next, in step S03, after initially imaging to locate each marker, straight-line cutting is performed along the aligned edges of the dies. In step S04, after rotating the wafer by an angle and imaging to locate each marker, straight-line cutting is performed along the aligned, uncut edges of the dies. Finally, in step S05, the previous step is repeated until all edges of each die have been straight-line cut. Descriptions of the components involved in the aforementioned process steps can be referenced above and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A manufacturing method for dicing a wafer having multiple non-rectangular dies, comprising:
arranging the non-rectangular dies on the wafer such that the edges of each of the non-rectangular dies are aligned in a straight line and forming partitions among each of the adjacent non-rectangular dies wherein each of the partitions is smaller than each of the non-rectangular dies;
disposing multiple markers individually in each of the partitions;
performing a straight-line cut to the wafer along the aligned edges of the non-rectangular dies after initially imaging to locate each of the markers;
performing another straight-line cut to the wafer along another set of the aligned and uncut edges of the non-rectangular dies after rotating the wafer to an angle and imaging to locate each of the markers; and
repeating the previous steps until all of the edges of each of the non-rectangular dies been straight-line cut.

2. The manufacturing method for dicing a wafer of claim 1, wherein when each of the non-rectangular dies is a 120° internal-angle die, the aligned edges of the 120° internal-angle dies on the wafer are aligned to form multiple first slope straight lines, multiple second slope straight lines and multiple third slope straight lines.

3. The manufacturing method for dicing a wafer of claim 2, wherein the step of initially imaging to locate each of the markers is to perform a straight-line cut to each of the first slope straight lines on the wafer after locating each of the first slope straight lines to a horizontal status.

4. The manufacturing method for dicing a wafer of claim 3, wherein the step of rotating the wafer to an angle and imaging to locate each of the markers is:
performing a straight-line cut to each of the second slope straight lines on the wafer after rotating the wafer with a 60° angle to locate each of the second slope straight lines to the horizontal status; and
performing a straight-line cut to each of the third slope straight lines on the wafer after rotating the wafer with another 60° angle to locate each of the third slope straight lines to the horizontal status.

5. The manufacturing method for dicing a wafer of claim 1, wherein the step of perform a straight-line cut to the wafer is to cut with a dicing saw.

6. The manufacturing method for dicing a wafer of claim 1, wherein the step of disposing multiple markers individually in each of the partitions is to perform a photolithography process to form each of the markers in each of the partitions.

7. The manufacturing method for dicing a wafer of claim 2, wherein the step of forming partitions among each of the adjacent non-rectangular dies on the wafer is to arrange each of the adjacent non-rectangular dies on the wafer surrounded to form triangular areas.

8. A manufacturing method for dicing a wafer having multiple hexagonal dies, comprising:
arranging the hexagonal dies on the wafer such that the edges of each of the hexagonal dies are aligned to form multiple first slope straight lines, multiple second slope straight lines and multiple third slope straight lines and forming partitions among each of the adjacent hexagonal dies wherein each of the partitions is smaller than each of the hexagonal dies;
disposing multiple markers individually in each of the partitions;
performing a straight-line cut to the wafer along each of the first slope straight lines after initially imaging to locate each of the markers to locate each of the first slope straight lines to a horizontal status;
performing a second straight-line cut to the wafer along each of the second slope straight lines after rotating the wafer with a 60° angle to image to locate each of the markers to locate each of the second slope straight lines to the horizontal status; and
performing a third straight-line cut to the wafer along each of the third slope straight lines after rotating the wafer with another 60° angle to image to locate each of the markers to locate each of the third slope straight lines to the horizontal status.

9. The manufacturing method for dicing a wafer of claim 8, wherein the step of perform a straight-line cut to the wafer is to cut with a dicing saw.

10. The manufacturing method for dicing a wafer of claim 8, wherein the step of disposing multiple markers individually in each of the partitions is to perform a photolithography process to form each of the markers in each of the partitions.

11. The manufacturing method for dicing a wafer of claim 8, wherein the step of forming partitions among each of the adjacent hexagonal dies on the wafer is to arrange each of the adjacent hexagonal dies on the wafer surrounded to form triangular areas.
